(19) United States
(12) Patent Application Publication
(10) Pub. No.: US 2014/0063699 A1
(43) Pub. Date: Mar. 6, 2014

(54) DISPLAY DEVICE

(71) Applicant: Sony Corporation, Minato-ku (JP)

(72) Inventor: Daisuke NEZU, Tokyo (JP)

(21) Appl. No.: 13/917,820

(22) Filed: Jun. 14, 2013

(30) Foreign Application Priority Data
Aug. 30, 2012 (JP) 2012-189815

(51) Int. Cl. H05K 5/00

(52) U.S. Cl. CPC H05K 5/0017
USPC 361/679.01

(57) ABSTRACT

Provided is a display device, including: a display main body configured to display an image; a bezel including frames surrounding the display main body, the bezel being structured by connecting the frames at a corner portion of the display main body; a first plate member bending in an L shape at the corner portion of the display main body, the first plate member aligning the frames; a second plate member bending in an L shape at the corner portion of the display main body, the second plate member connecting the frames aligned by the first plate member; and a fixing member fixing the first plate member and the second plate member on a surface of the bezel, the surface being orthogonal to a surface of the display main body.

### BACKGROUND

The present disclosure relates to a display device. Specifically, the present disclosure relates to, for example, a display device, which precisely connects a plurality of frames structuring a bezel of a display main body and which may have the bezel having a narrow width.

In the past, for example, there is known a following method of structuring a bezel of a television receiver or the like. A plurality of frames are connected with each other, to thereby structure a bezel, which surrounds a display main body (for example, see Japanese Patent Application Laid open No. 2006-54177, Japanese Patent Application Laid open No. 2006-267755, Japanese Patent

Application Laid open No. 2007-86625, and Japanese Patent Application Laid open No. 2008-52039).

This structuring method may utilize materials with less waste than a case of manufacturing a bezel by punching or the like, for example. As a result, the manufacturing cost may be reduced.

### SUMMARY

However, according to the prior structuring method, the width of a bezel may be large depending on the structure for connecting frames. Further, there may be a gap at a connection portion of the frames.

In view of the above-mentioned circumstances, it is desirable to provide a display device, which may precisely connect a plurality of frames and which may have a bezel having a narrow width.

According to an embodiment of the present disclosure, there is provided a display device, including: a display main body configured to display an image; a bezel including frames surrounding the display main body, the bezel being structured by connecting the frames at a corner portion of the display main body; a first plate member bending in an L shape at the corner portion of the display main body, the first plate member aligning the frames; a second plate member bending in an L shape at the corner portion of the display main body, the second plate member connecting the frames aligned by the first plate member; and a fixing member fixing the first plate member and the second plate member on a surface of the bezel, the surface being orthogonal to a surface of the display main body.

The first plate member may include one portion and the other portion of the first plate member bending in the L shape at the corner portion of the display main body, the one portion being inserted in a first frame, the other portion being inserted in a second frame, the second frame being connected to the first frame, the first plate member thus aligning the first frame with the second frame. The second plate member may include one portion and the other portion of the second plate member bending in the L shape at the corner portion of the display main body, the one portion including a protrusion portion, the first frame including a concave portion inside the first frame, the protrusion portion of the one portion being fitted in the concave portion of the first frame, the other portion including a protrusion portion, the second frame including a concave portion inside the second frame, the protrusion portion of the other portion being fitted in the concave portion of the second frame, the second plate member thus connecting the first frame and the second frame.

The fixing member may be a screw. The first plate member may include a screw hole and the second plate member includes a screw hole, the screw holes being capable of receiving the screw, the screw holes being formed by using the same tool.

According to an embodiment of the present disclosure, the first plate member aligns the frames. The second plate member connects the frames, which are aligned by the first plate member. The fixing member fixes the first plate member and the second plate member on a surface of the bezel, the surface being orthogonal to a surface of the display main body.

According to the present disclosure, there may be provided a display device, which may precisely connect a plurality of frames and which may have a bezel having a narrow width.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing an example of the appearance of a television receiver, which includes a bezel having a narrow width;

FIG. 2 is a diagram showing a plurality of members provided on a corner portion of the bezel;

FIG. 3 is a sectional view showing a state where the frames are connected; and

FIG. 4 is a sectional view of the bezel seen from the left side of FIG. 3.

### DETAILED DESCRIPTION OF EMBODIMENTS

Hereinafter, an embodiment (hereinafter referred to as this embodiment) of the present disclosure will be described with reference to the drawings. Note that description will be made in the following order.

1. This embodiment (example in which frames are connected at corner portion of display main body)

2. Modification

### 1. This Embodiment

[Outline of Present Disclosure]

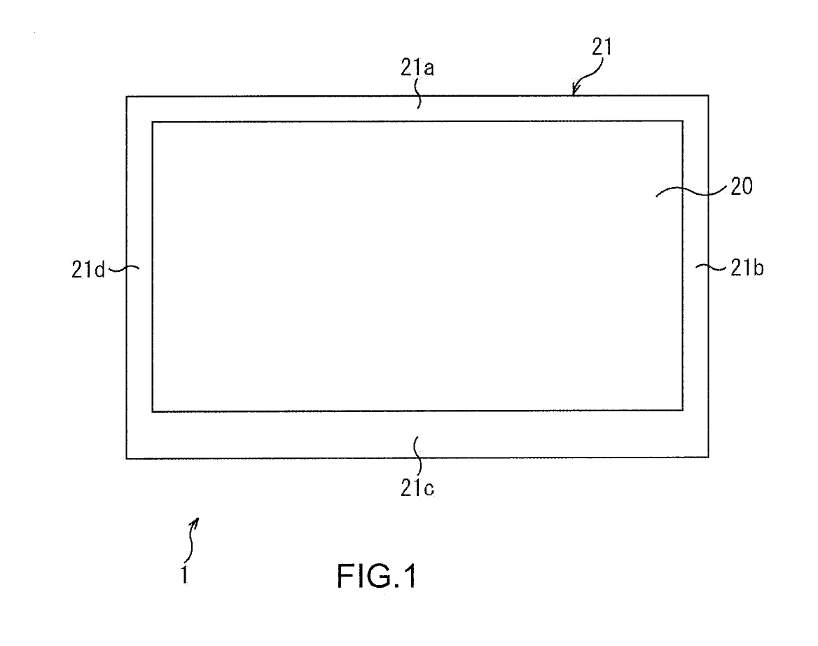

FIG. 1 is a diagram showing an example of the appearance of a television receiver 1 of this embodiment.

The television receiver 1 includes a display main body 20 and a bezel 21. The display main body 20 is configured to display an image. The bezel 21 surrounds the display main body 20. Note that the bezel 21 includes a plurality of frames 21a to 21d. The frames 21a to 21d are made of metal such as aluminum alloy, for example.

Further, the frames 21a to 21d are connected with each other at the corner portions of the display main body 20. The corner portions of the display main body 20 are the corner portions of the bezel 21, which bend at a right angle. That is, in FIG. 1, the frame 21a connects with the frame 21b at an upper-right (of FIG. 1) corner portion of the display main body 20. The frame 21b connects with the frame 21c at a lower-right (of FIG. 1) corner portion of the display main body 20.

Further, in FIG. 1, the frame 21c connects with the frame 21d at a lower-left (of FIG. 1) corner portion of the display main body 20. The frame 21d connects with the frame 21a at an upper left (of FIG. 1) corner portion of the display main body 20.

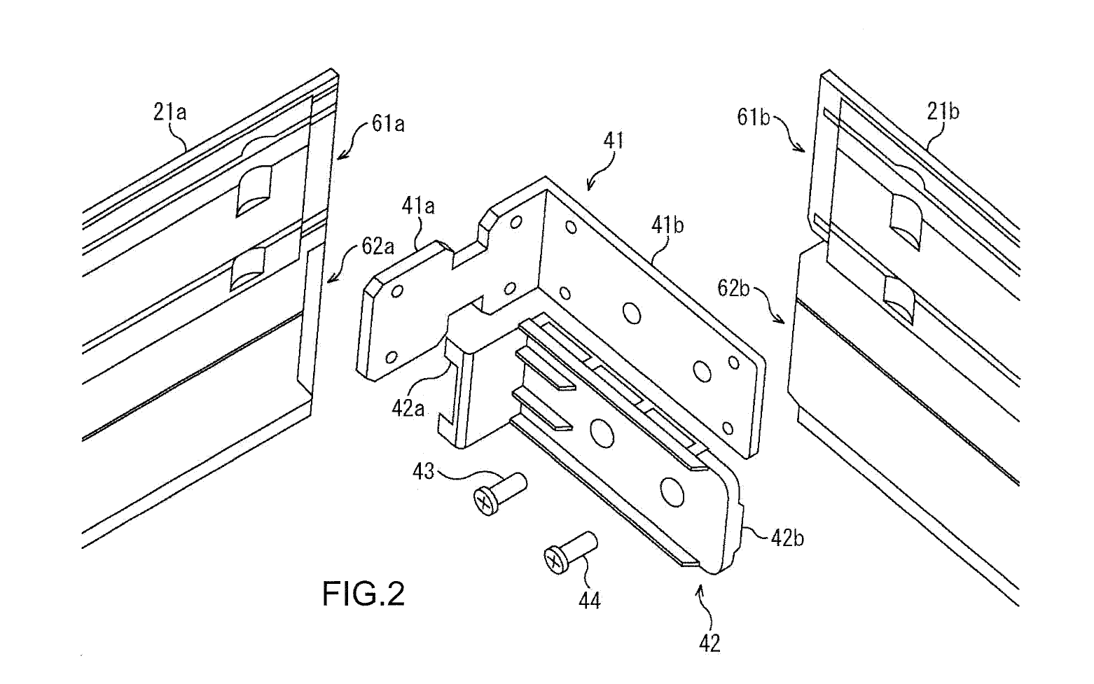

Next, FIG. 2 shows an example of members provided on each corner portion of the bezel 21.

Each of plate members 41 and 42 is a plate member bending in an L shape. The plate members 41 and 42 connect the frame 21a and the frame 21b. Further, for example, fixing members 43 and 44 fix the plate members 41 and 42 on the frame 21b.

Here, as shown in FIG. 2, screws or the like may be used as the fixing members 43 and 44, for example.

The plate member 41 aligns the frame 21a with the frame 21b.

That is, for example, one portion 41a of the plate member 41 is inserted in an insertion slot 61a of the frame 21a. The other portion 41b of the plate member 41, which bends in an L shape, is inserted in an insertion slot 61b of the frame 21b. The plate member 41 aligns the frame 21a with the frame 21b in this manner.

Further, as shown in FIG. 2, the other portion 41b of the plate member 41 includes screw holes. The screws being the fixing members 43 and 44 are inserted in the screw holes, respectively.

The plate member 42 connects the frame 21a and the frame 21b in the state where the plate member 41 aligns the frame 21a with the frame 21b.

That is, for example, one portion 42a of the plate member 42 is in a void portion 62a of the frame 21a, and connects with the frame 21a. The other portion 42b of the plate member 42, which bends in an L shape, is in a void portion 62b of the frame 21b, and connects with the frame 21b. As a result, the frame 21a connects with the frame 21b.

Further, as shown in FIG. 2, the other portion 42b of the plate member 42 includes screw holes. The screws being the fixing members 43 and 44 are inserted in the screw holes, respectively.

Note that the screw holes are provided on the other portion 41b of the plate member 41 and the other portion 42b of the plate member 42 by using the same kind of fabricating equipment (for example, tool bit, etc.). Because of this, the cost of shaping the screw holes may be smaller than a case where different kinds of fabricating equipment is used, for example.

The fixing members 43 and 44 are, for example, screws or the like. The fixing members 43 and 44 are inserted in the screw holes formed on the other portion 42b of the plate member 42, and in the screw holes formed on the other portion 41b of the plate member 41. Then, the fixing members 43 and 44 are put into an inner wall, which surrounds the void portion 62b of the frame 21b.

Here, each screw hole may or may not have a spiral groove. Let's say that the inner side of the screw hole is not tapped and a spiral groove is not provided. Then, the cost of shaping the screw holes may be further reduced.

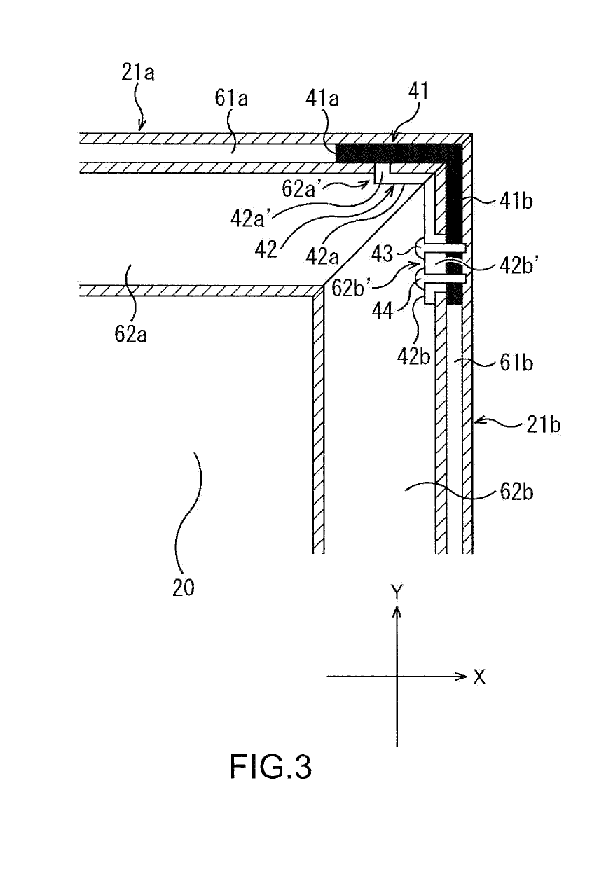

Next, FIG. 3 is a sectional view showing a state where the frame 21a connects with the frame 21b.

The one portion 41a of the plate member 41 is inserted in the insertion slot 61a of the frame 21a. The other portion 41b of the plate member 41, which bends in an L shape, is inserted in the insertion slot 61b of the frame 21b.

The plate member 41 aligns the frame 21a with the frame 21b in this manner. That is, as shown in FIG. 3, the plate member 41 connects the frame 21a and the frame 21b. In this state, the insertion slot 61a of the frame 21a aligns with the insertion slot 61b of the frame 21b. Further, the void portion 62a of the frame 21a aligns with the void portion 62b of the frame 21b.

As a result, the plate member 42 may connect the frame 21a and the frame 21b precisely.

Further, the plate member 41 fixes the frame 21a such that the frame 21a is not misaligned in the vertical direction (Y direction) of FIG. 3. The plate member 41 fixes the frame 21b such that the frame 21b is not misaligned in the horizontal direction (X direction) of FIG. 3.

The one portion 42a of the plate member 42 includes a protrusion portion 42a′. A concave portion 62a′ is provided on an upper (of FIG. 3) wall (surface orthogonal to surface of display main body 20) out of the walls surrounding the void portion 62a of the frame 21a. The protrusion portion 42a′ is fitted in the concave portion 62a′.

Further, the other portion 42b of the plate member 42 includes a protrusion portion 42b′. A concave portion 62b′ is provided on a right (of FIG. 3) wall (surface orthogonal to surface of display main body 20) out of the walls surrounding the void portion 62b of the frame 21b. The protrusion portion 42b′ is fitted in the concave portion 62b′.

As a result, the frame 21a is fixed such that the frame 21a is not misaligned in the X direction of FIG. 3. The frame 21b is fixed such that the frame 21b is not misaligned in the Y direction of FIG. 3.

The fixing members 43 and 44 are, for example, screws or the like. The fixing members 43 and 44 are put into the other portion 42b of the plate member 42 and the other portion 41b of the plate member 41 in a left-to-right direction of FIG. 3.

As a result, the fixing members 43 and 44 fix the plate members 41 and 42 on a right (of FIG. 3) wall out of the walls surrounding the void portion 62b of the frame 21b.

Because of this, the width (length in horizontal direction of FIG. 3) of the frame 21b may be smaller than the width in a case where the fixing members 43 and 44 are put in the front-to-depth direction (of FIG. 3), for example. In addition, the width of the bezel 21 may be narrowed.

Further, for example, the screws being the fixing members 43 and 44 are put into the right (of FIG. 3) wall out of the walls surrounding the void portion 62b of the frame 21b. As a result, the bezel 21 may be manufactured easier than a case where a member, which is dedicated to putting the screws, is additionally provided. As a result, the manufacturing cost of the television receiver 1 may be reduced.

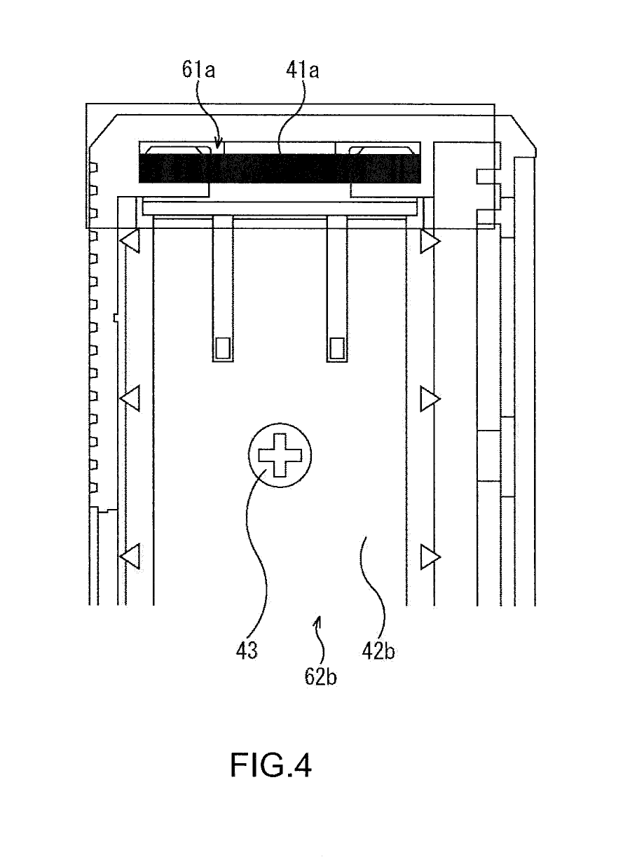

Next, FIG. 4 is a sectional view showing a state where the frame 21a of FIG. 3 is seen from the left side of FIG. 3.

As shown in FIG. 4, the one portion 41a of the plate member 41 is inserted in the insertion slot 61a of the frame 21a.

Further, the screw being the fixing member 43 is fixed on the plate member 42b, which bends in an L shape, in the void portion 62b.

### 2. Modification

In this embodiment, a method of connecting the bezel 21 to the television receiver 1 has been described. Alternatively, the present technology may be applied to a bezel, which is provided on any display device configured to display an image.

Note the present technology may employ the following structures.

(1) A display device, comprising:
a display main body configured to display an image;
a bezel including frames surrounding the display main body, the bezel being structured by connecting the frames at a corner portion of the display main body;
a first plate member bending in an L shape at the corner portion of the display main body, the first plate member aligning the frames;
a second plate member bending in an L shape at the corner portion of the display main body, the second plate member connecting the frames aligned by the first plate member; and
a fixing member fixing the first plate member and the second plate member on a surface of the bezel, the surface being orthogonal to a surface of the display main body.

(2) The display device according to (1), wherein
the first plate member includes one portion and the other portion of the first plate member bending in the L shape at the corner portion of the display main body, the one portion being inserted in a first frame, the other portion being inserted in a second frame, the second frame being connected to the first frame, the first plate member thus aligning the first frame with the second frame, and
the second plate member includes one portion and the other portion of the second plate member bending in the L shape at the corner portion of the display main body, the one portion including a protrusion portion, the first frame including a concave portion inside the first frame, the protrusion portion of the one portion being fitted in the concave portion of the first frame, the other portion including a protrusion portion, the second frame including a concave portion inside the second frame, the protrusion portion of the other portion being fitted in the concave portion of the second frame, the second plate member thus connecting the first frame and the second frame.

(3) The display device according (1) or (2), wherein
the fixing member is a screw, and
the first plate member includes a screw hole and the second plate member includes a screw hole, the screw holes being capable of receiving the screw, the screw holes being formed by using the same tool.

The present disclosure contains subject matter related to that disclosed in Japanese Priority Patent

Application JP 2012-189815 filed in the Japan Patent Office on Aug. 30, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device, comprising:
a display main body configured to display an image;
a bezel including frames surrounding the display main body, the bezel being structured by connecting the frames at a corner portion of the display main body;
a first plate member bending in an L shape at the corner portion of the display main body, the first plate member aligning the frames;
a second plate member bending in an L shape at the corner portion of the display main body, the second plate member connecting the frames aligned by the first plate member; and
a fixing member fixing the first plate member and the second plate member on a surface of the bezel, the surface being orthogonal to a surface of the display main body.

2. The display device according to claim 1, wherein
the first plate member includes one portion and the other portion of the first plate member bending in the L shape at the corner portion of the display main body, the one portion being inserted in a first frame, the other portion being inserted in a second frame, the second frame being connected to the first frame, the first plate member thus aligning the first frame with the second frame, and
the second plate member includes one portion and the other portion of the second plate member bending in the L shape at the corner portion of the display main body, the one portion including a protrusion portion, the first frame including a concave portion inside the first frame, the protrusion portion of the one portion being fitted in the concave portion of the first frame, the other portion including a protrusion portion, the second frame including a concave portion inside the second frame, the protrusion portion of the other portion being fitted in the concave portion of the second frame, the second plate member thus connecting the first frame and the second frame.

3. The display device according to claim 2, wherein
the fixing member is a screw, and
the first plate member includes a screw hole and the second plate member includes a screw hole, the screw holes being capable of receiving the screw, the screw holes being formed by using the same tool.
